(19) United States
(12) Patent Application Publication
(10) Pub. No.: US 2008/0054933 A1
(43) Pub. Date: Mar. 6, 2008

(54) SCAN CHAIN IN A CUSTOM ELECTRONIC CIRCUIT DESIGN

(76) Inventors: Dirk Franger, Mannheim (DE); Pascal Witte, Freiburg (DE); Armin Windschiegl, Weil im Schoenbuch (DE)

Correspondence Address: IBM MICROELECTRONICS;INTELLECTUAL PROPERTY LAW, 1000 RIVER STREET, 972 E, ESSEX JUNCTION, VT, 05452, US

(21) Appl. No.: 11/850,709

(22) Filed: Sep. 6, 2007

(30) Foreign Application Priority Data
Sep. 6, 2006 (DE) 06120195.0

(51) Int. Cl. H03K 19/00

(52) U.S. Cl. 326/16

(57) ABSTRACT

The present invention relates to a scan chain and related cell design structures in a custom electronic circuit design with a plurality of storage elements. All scan inputs and all scan outputs of the storage elements are propagated to a top level of the design hierarchy in design. Each scan input and each scan output on the top level is declared a primary input and primary output, respectively. Propagating all the inputs and outputs of the storage elements to this level improves the wireability of the scan chain.

### CROSS REFERENCES TO RELATED APPLICATIONS

This application is related to German Patent Application No. 06120195.0, filed Sep. 06, 2006 and IBM Docket No. DE920060041US1 filed contemporaneously with this Application.

### FIELD OF THE INVENTION

The present invention relates to a method for generating a scan chain in a custom electronic circuit design.

### BACKGROUND OF INVENTION

### Description of the Related Art

Given the complexity of today's electronic circuits, formal descriptions of electronic circuits at various abstraction levels are being created by computer-aided design tools before any real hardware is created during the development of an electronic circuit. These descriptions are called designs or design structures of the associated electronic circuits and the process of creating these descriptions is called the electronic circuit design.

Cell-based integrated circuit design methodologies employ design automation tools to place predesigned elements or circuit structures such as logic gates and latches taken from a library (“cells”) instead.

Custom electronic circuit design means control over the circuit style and topology, device sizes, and the physical design of both transistors and interconnects. Minimizing both parasitics and the number of stage delays incurred to implement a particular function are keys in attaining a high frequency. Computer-aided design tools do not always provide the flexibility to allow the designer enough control to arrive at the optimal solution. Accordingly, a significant amount of custom electronic circuit design tends to be manually driven, resulting in far less productivity than that of a designer using a cell-based methodology. For example, in a processor design a large fraction of the logic is irregular and cannot be separated into multiple instances of similar or identical logic. Besides being used for integrated circuits, custom electronic circuit design is also performed in the development of printed circuit boards.

A full custom electronic circuit design includes a plurality of storage elements. For example the storage element may be a flip-flop or a latch. The storage elements are interconnected via logical gates according to the function and the purpose of the custom circuit. These interconnected logical gates form a Boolean logical network, which is often simply called network. Every storage element carries the information of one bit and comprises a data input and a data output. The data input and the data output are provided for the connection to the logical gates.

Typically, custom electronic circuit designs have a hierarchical structure with several levels. A number of storage elements with the according logical gates are combined to a cell and interconnected within said cell. Several identical or different cells may be combined to a larger cell on a higher level.

For testing purposes of the custom electronic circuit design often all storage elements are interconnected to a so-called scan chain. For this purpose each storage element includes a scan input and a scan output. The scan chain includes a plurality of connections between a scan output of one storage element and a scan input of the next storage element. The scan chain is a serial line moving a data bit into each storage element according to a predetermined scheme. In test mode said scan chain has the functionality of a shift register.

The ordering of the scan chain elements or design structures can be determined by applying different criteria. Usually electrical properties and wireability issues are considered, for which it is advantageous if said scan chain is as short as possible.

The development of the custom electronic circuit design usually starts with a specification. A formalized refinement of said specification can be performed using a hardware description language (HDL) such as VHDL or Verilog. A VHDL (Very High Speed Integrated Circuit Hardware description language) description is a formalized description of the custom circuit's functionality. A schematic is a graphical, formalized description of an electronic circuit, its elements and their interconnections. A layout is a geometrical and physical representation of the custom electronic circuit design. In the following descriptions it is assumed that a layout can be automatically generated from the schematic.

In an early design phase the designer creates a schematic based on the formalized description of the design. At this stage no placement information can be considered for scan chain ordering. Thus, at first the scan chain is ordered randomly.

The elements of the scan chain in the schematic must be in the identical order as stated in HDL description to verify that the schematic corresponds to the HDL description. This correspondence is checked by a formal verification tool such as “Verity”. The tool “Verity” is a Boolean equivalence checker described in the article “Verity—a formal verification program for custom CMOS circuits” by A. Kuehlmann, A. Srinivasan and D. P. LaPotin (IBM J. Res. Develop. Vol. 39, No. 1/2, 1995).

When a placement of a design has been created the designer manually reorders the design structure elements logically within the scan chain. Then the order of the scan chain in the HDL description has to be changed accordingly to correspond to the order of the scan chain in the schematic. If design changes are necessary the circuit designer has to iterate over the above steps.

The article “Layout scan insertion and schematic back-annotation for at speed test” by Tron Womack and Fernando Torre (IPCOM07698D, Motorola TDB, 1996) describes a method of forming a layout with a scan chain. In this method, storage elements are placed on the substrate before the scan chain connections between said storage elements are defined. After cells have been placed the scan chain is created. The schematic has a hierarchical structure, but the layout is flattened to standard cells.

### SUMMARY OF THE INVENTION

It is an object of the present invention to provide an improved cell design structure and method for generating a scan chain in a custom electronic circuit design.

The above object is achieved by a design structure as laid out in the independent claims. Further advantageous embodiments of the present invention are described in the dependent claims and are taught in the description below.

The core idea of the invention is the propagation of every scan input and output to the top level of the design hierarchy. The order of the scan chain is independent of the design's logical structure including storage elements and logic gates. The design hierarchy is maintained in the schematic as well as in the layout. The substantial advantage of the invention is the maximum flexibility of the wiring of the scan chain.

The propagation of scan inputs and scan outputs to the top level allows the determination of the position of all storage elements without analyzing each relevant sub-cell and without substantial calculations.

### BRIEF DESCRIPTION OF THE DRAWINGS

The above as well as additional objectives, features and advantages of the present invention become apparent in the following detailed written description.

The novel and inventive features believed to the characteristics of the invention are set forth in the appended claims. The invention itself and its advantages are best understood by reference to the following detailed description of preferred embodiments in conjunction with the accompanied drawings, wherein:

FIG. 1 shows a flow chart diagram that illustrates a first part of a method according to a preferred embodiment of the present invention,

FIG. 2 shows a flow chart diagram that illustrates a second part of the method according to the preferred embodiment of the present invention,

FIG. 3 shows a diagram that illustrates a part of a custom circuit with a scan chain generated by the method according to the present invention, and

FIG. 4 shows a diagram that represents a part of a custom circuit as shown in FIG. 3 that contains a scan chain built by applying the method according to prior art.

FIG. 5 shows a flow diagram of a design process used in semiconductor design.

### DETAILED DESCRIPTION

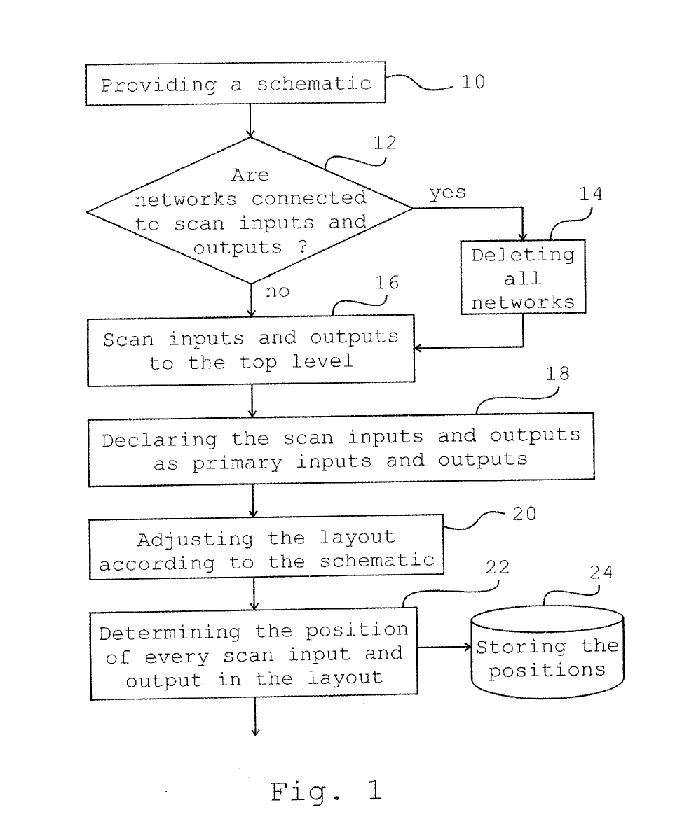

FIG. 1 shows a flow chart diagram that illustrates a first part of a method of using the scan chain cell design structure according to a preferred embodiment the present invention.

In a step 10 a schematic of a custom circuit is provided. The schematic is a structural description of said custom circuit, its electronic elements and their interconnections. The schematic is created on basis of an HDL description, which is a formalized representation of the logic in a custom circuit. Initially the scan chain in the HDL description is in an unspecific order. During the initial creation of the schematic and the following placement the order of the scan chain is ignored. At this stage it is not mandatory that the scan chain in the schematic corresponds to the scan chain in the HDL description.

In a step 12 it is checked if any networks are connected to the scan inputs and scan outputs of any storage element. In this case said networks are deleted on every level of the schematic in a step 14.

According to a step 16 the scan input and scan output of each storage element is propagated to the top level of the design hierarchy. After this step 16 the scan inputs and scan outputs of all storage elements are accessible from said top level of the design hierarchy. This allows an optimal flexibility for the wiring of the scan chain. The scan inputs and scan outputs are independent of the hierarchy level a storage element is contained. The scan inputs and scan outputs of each storage element are accessible from the top level of the design hierarchy.

In a step 18 the scan inputs and scan outputs of all storage elements are declared as primary inputs and primary outputs, respectively. This means that they are not connected to other signal sources or sinks and allows easy determinations of the position of each scan input and scan output and therefore the position of each storage element in the layout.

In a step 20 either a new layout of the custom circuit is created or an existing layout is modified according to the modifications of the schematic in the step 18. The layout describes the geometrical and physical representation of the custom electronic circuit design. Since the scan inputs and scan outputs of all storage elements are declared as primary inputs and primary outputs, the pin positions for said inputs and outputs can be determined for the creation of the scan chain.

In a step 22 the position of each scan input and scan output in the layout is determined.

The positions of each scan input and scan output are stored in a data structure together with the names of the storage elements according to the step 24.

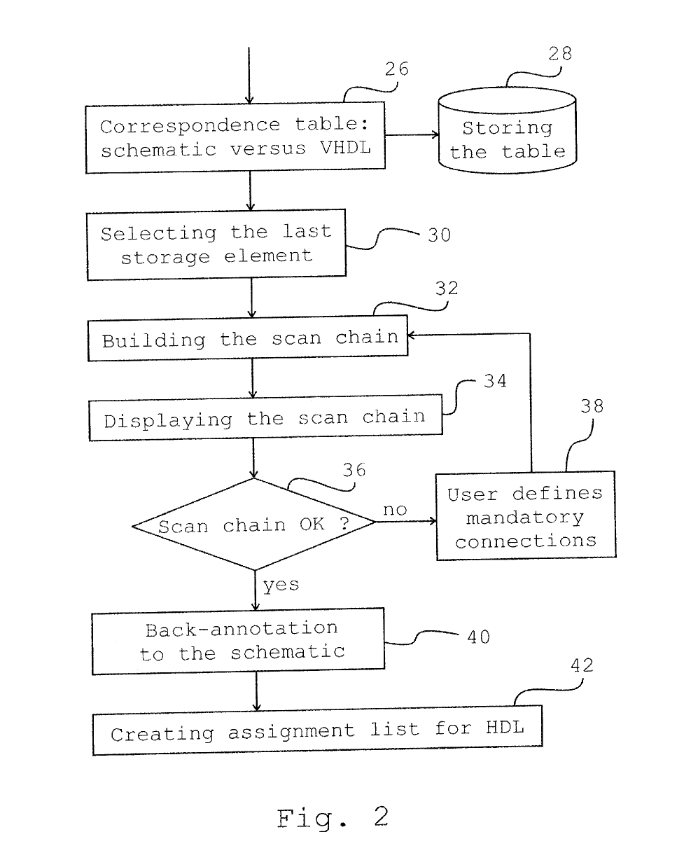

The continuation of the flow chart diagram of the inventive method is illustrated in FIG. 2.

In a step 26 a correspondence table is composed. In said correspondence table the name of each storage element in the schematic corresponds to an according name of a storage element in the HDL description. The correspondence table is stored in a step 28.

The last storage element of the scan chain is selected manually or automatically in a step 30. For example, either the first or the last storage element of the scan chain is selected.

A predetermined algorithm orders the elements of the scan chain in a step 32 by using the data of the step 24. If for example the last storage element has been selected in the step 30 before, the scan chain is built up backwards. The algorithm may comprise a condition that the connection between two storage elements on the same vertical position has a higher priority than the connection between two storage elements of different vertical positions. Using such conditions the scan chain mostly results in a meander structure.

In a step 34 the scan chain is displayed graphically in the layout. In a step 36 the user can check the scan chain and make any changes by defining mandatory connections between the storage elements in a step 38. Such mandatory connections between storage elements are taken into account in a further iteration in the step 32. The result of said repeated step 32 is displayed to the user in the layout again according to the step 34.

If the user accepts the proposed scan chain at last, the new scan chain is back-annotated to the top level of the schematic in a step 40. Then all primary scan inputs and scan outputs declared in the step 18 are deleted. Only the scan input of the first storage element in the scan chain is defined as primary input. Further only the scan output of the last storage element in the scan chain is defined as primary output. This is updated accordingly in the layout.

In a step 42 an assignment list for the HDL description is created. The assignment list is inserted into the HDL description. Then the HDL description corresponds to the schematic, i.e. the representation of the scan chain in the HDL description is identical to its representation in the schematic.

Instead of selecting the last storage element of the scan chain in the step 30, alternatively the first storage element of the scan chain may be selected in the step 30. In this case the scan chain is built up forwards beginning with the first storage element.

Further the scan chain may be divided into two or more partial chains. In this case the first and/or the last storage elements of said partial chains have to be defined in step 30.

In a further embodiment, instead of selecting the last or first storage element of the scan chain according to the step 30, the scan output or scan input, respectively, may be selected at first.

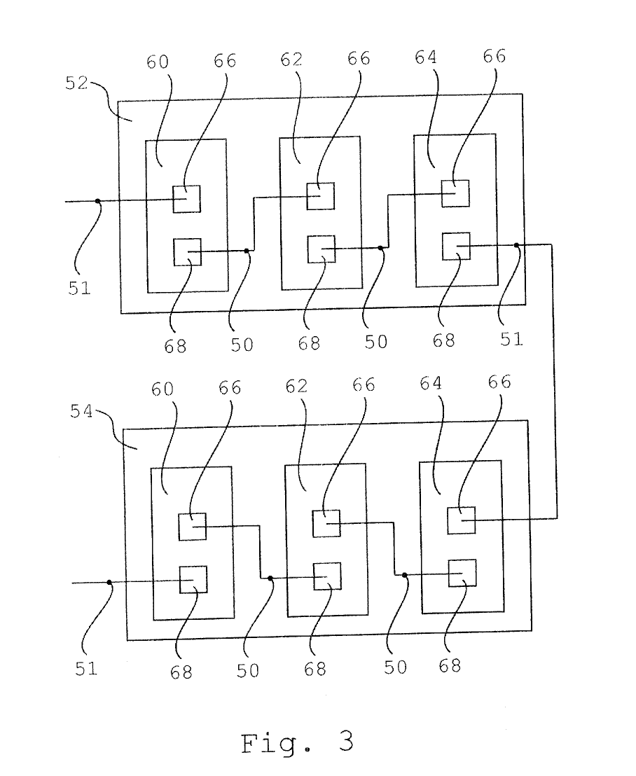

FIG. 3 illustrates a diagram of a part of a custom circuit with a scan chain of the method according to the present invention.

Said part of the custom circuit comprises a first cell 52 and a second cell 54. The first cell 52 includes a first storage element 60, a second storage element 62 and a third storage element 64. The second cell 54 also includes the first storage element 60, the second storage element 62 and the third storage element 64. The first cell 52 and the second cell 54 are identical. Each storage element 60, 62 and 64 comprises a scan input 66 and a scan output 68. The scan output 68 of one storage element 60, 62 and 64 is connected to the scan input 66 of the next storage element 60, 62 or 64 within the first cell 52 or the second cell 54, respectively, via internal interconnections 50.

The scan output 68 of the third storage element 64 in the first cell 52 is connected to the scan input 66 of the third storage element 64 in the second cell 54 via the internal interconnection 50. The scan input 66 of the first storage element 60 in the first cell 52 may be connected to any further scan output or to a primary input of the scan chain via the internal interconnection 50. The scan input 68 of the first storage element 60 in the second cell 54 may be connected to any further scan input or to a primary output of the scan chain via the internal interconnection 50.

Regarding their functionality the first cell 52 and the second cell 54 are identical. Their storage elements 60, 62 and 64 are interconnected according to the same scheme by logical gates via data input and data outputs, which are not shown in FIG. 3.

However, the scan inputs 66 and scan outputs 68 of the storage elements 60, 62 and 64 in FIG. 3 are connected by the internal interconnections 50 in such a way that the geometrical length of the scan chain is as short as possible. The order of the storage elements 60, 62 and 64 along the scan chain is independent of the logical function of the circuit. The storage elements 60, 62 and 64 in the first cell 52 have the following order along the scan chain: first storage element 60, second storage elements 62 and third storage element 64. The storage elements 60, 62 and 64 in the second cell 54 have the following order along the scan chain: third storage element 64, second storage elements 62 and first storage element 60. In the first cell 52 and in the second cell 54 the storage elements 60, 62 and 64 have an inverse order along the scan chain.

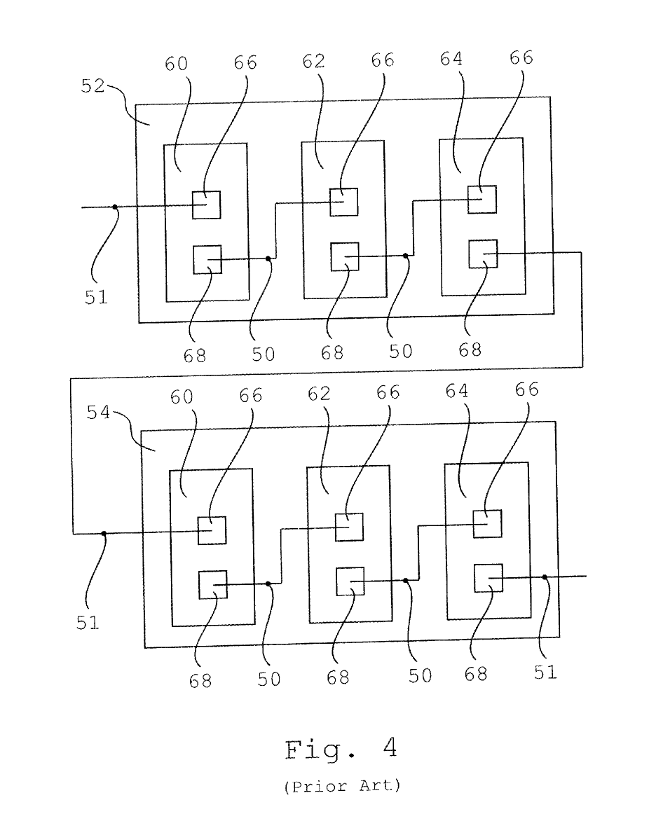

FIG. 4 shows the diagram of the part of the custom circuit according to FIG. 3 with a scan chain built by a method according to prior art. The part of the custom circuit in FIG. 4 has the same elements as in FIG. 3. There are also a first cell 52 and second cell 54. The first cell 52 includes the first storage element 60, the second storage element 62 and the third storage element 64. The second cell 54 includes also the first storage element 60, the second storage element 62 and the third storage element 64. According to prior art the scan input and scan output of each storage element are not propagated to the top level of the design hierarchy, therefore the scan chain wiring must be routed within the cells 52 and 54, respectively. Each storage element 60, 62 and 64 comprises a scan input 66 and a scan output 68. The scan output 68 of one of the storage elements 60, 62 and 64 is connected to the scan input 66 of a next storage element 60, 62 or 64 within the first cell 52 or within the second cell 54, respectively, via an external interconnection 51.

The scan output 68 of the third storage element 64 in the first cell 52 is connected to the scan input 66 of the first storage element 60 in the second cell 54 via the external interconnection 51. The scan input 66 of the first storage element 60 in the first cell 52 may be connected to any further scan output or to the primary input of the scan chain via the external interconnection 51. The scan output 68 of the third storage element 64 in the second cell 54 may be connected to any further scan input or to the primary output of the scan chain via the external interconnection 51.

Regarding their functionality the first cell 52 and the second cell 54 are identical. Their storage elements 60, 62 and 64 are interconnected according to the same scheme by logical gates via data input and data outputs, which are not shown in FIG. 4.

As the routing of the scan chain is done internally in cell 52 and 54 the storage elements 60, 62 and 64 in the first cell 52 and in the second cell 54 consequently have the same order along the scan chain.

The comparison of FIG. 3 and FIG. 4 clarifies the difference between the methods according to the present invention and prior art.

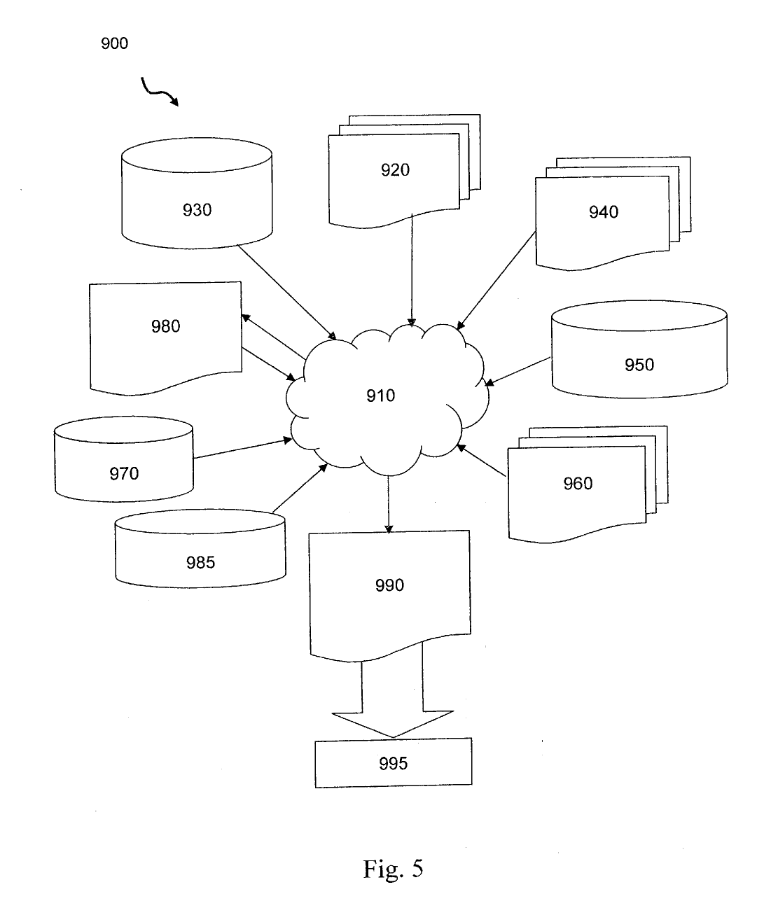

FIG. 5 shows a block diagram of an example design flow 900 which could be used to instantiate the cells of FIG. 3 according to the methodology taught by this invention. Design flow 900 may vary depending on the type of IC being designed. For example, a design flow 900 for building an application specific IC (ASIC) may differ from a design flow 900 for designing a standard component. Design structure 920 is preferably an input to a design process 910 and may come from an IP provider, a core developer, or other design company or may be generated by the operator of the design flow, or from other sources. Design structure 920 comprises circuit 100 in the form of schematics or HDL, a hardware-description language (e.g., Verilog, VHDL, C, etc.). Design structure 920 may be contained on one or more machine readable medium. For example, design structure 920 may be a text file or a graphical representation of circuit 100. Design process 910 preferably synthesizes (or translates) circuit 100 into a netlist 980, where netlist 980 is, for example, a list of wires, transistors, logic gates, control circuits, I/O, models, etc. that describes the connections to other elements and circuits in an integrated circuit design and recorded on at least one of machine readable medium. This may be an iterative process in which netlist 980 is resynthesized one or more times depending on design specifications and parameters for the circuit.

Design process 910 may include using a variety of inputs; for example, inputs from library elements 930 which may house a set of commonly used elements, circuits, and devices, including models, layouts, and symbolic representations, for a given manufacturing technology (e.g., different technology nodes, 32 nm, 45 nm, 90 nm, etc.), design specifications 940, characterization data 950, verification data 960, design rules 970, and test data files 985 (which may include test patterns and other testing information). Design process 910 may further include, for example, standard circuit design processes such as timing analysis, verification, design rule checking, place and route operations, etc. One of ordinary skill in the art of integrated circuit design can appreciate the extent of possible electronic design automation tools and applications used in design process 910 without deviating from the scope and spirit of the invention. The design structure of the invention is not limited to any specific design flow.

Ultimately, design process 910 preferably translates circuit 100, along with the rest of the integrated circuit design (if applicable), into a final design structure 990 (e.g., information stored in a GDS storage medium). Final design structure 990 may comprise information such as, for example, test data files, design content files, manufacturing data, layout parameters, wires, levels of metal, vias, shapes, test data, data for routing through the manufacturing line, and any other data required by a semiconductor manufacturer to produce circuit 100. Final design structure 990 may then proceed to a stage 995 where, for example, final design structure 990: proceeds to tape-out, is released to manufacturing, is sent to another design house or is sent back to the customer.

It is an advantage of the present invention that the hierarchy of the design is maintained in the schematic as well as in the layout. Although the hierarchy in the layout is maintained, propagating scan input and scan output of each storage element to the top-level of the hierarchy allows a maximum of possibilities for connecting said storage elements. This results in a custom circuit according to FIG. 3 with a short geometrical and physical length of the scan chain. According to the present invention, the scan chain is ordered independently of the logical connection of the storage elements.

Additionally, propagating the scan inputs and scan outputs to the top level of the design hierarchy allow that the position of each storage element may be determined directly. It is not necessary to analyze the sub-cells in every level.

The inventive method is also suitable for generating a plurality of scan chains in a custom electronic circuit design. These scan chains may be used for parallel test cases.

The present invention can also be embedded in a computer program product which comprises all the features enabling the implementation of the methods described herein. Further, when loaded in a computer system, said computer program product is able to carry out these methods.

Although illustrative embodiments of the present invention have been described herein with reference to the accompanying drawings, it is to be understood that the present invention is not limited to those precise embodiments, and that various other changes and modifications may be affected therein by one skilled in the art without departing from the scope or spirit of the invention. All such changes and modifications are intended to be included within the scope of the invention as defined by the appended claims.

What is claimed is:

1. A design with structures embodied in a machine readable medium used in a design process for use as a scan chain, the design structure comprising:
the machine readable medium comprising a hierarchical design
a first and second identical cells, each cell having a plurality of storage elements;
each storage element comprising a scan input and a scan output with each storage elements output connected to the scan output of the adjacent storage element first and second storage elements;
said first and second cells being instantiated in the highest level hierarchy of the design such that its inputs and outputs are primary.

2. The design of claim 1 wherein the position of each scan input and scan output are stored in a data structure together with the names of the storage elements.

3. The design of claim 2 also comprising a correspondence table where the name of each storage element in a schematic representation of the storage elements corresponds to an according name of a storage element in the HDL description.

4. A design structure embodied in a machine readable medium used in a design process for use as a scan chain, the design structure comprising:
a first and second identical cells, each cell having a plurality of storage elements;
each storage element comprising a scan input and a scan output with each storage elements output connected to the scan output of the adjacent storage element first and second storage elements;
said first and second cells are connected to each other in a manner such that the storage element's inputs and outputs can be instantiated in the highest level hierarchy of a design as primary inputs and outputs.

5. The design structure of claim 4 where there are at least three storage elements in each cell.

6. The design structure of claim 5 where the storage elements are connected by wires that provide the shortest distance of travel for the scan chain.

7. The design structure of claim 4, wherein the scan chain is divided into at least two partial chains, each partial chain has a predetermined storage element.
